(19) United States
(12) Patent Application Publication
(10) Pub. No.: US 2026/0101815 A1
(43) Pub. Date: Apr. 9, 2026

(54) MONOLITHIC EMBEDDED GaN IN SILICON CMOS

(71) Applicant: Microchip Technology Incorporated, Chandler, AZ (US)

(72) Inventors: Steve Nagel, Chandler, AZ (US); Bomy Chen, Newark, CA (US); Damian McCann, Rossmoor, CA (US)

(73) Assignee: Microchip Technology Incorporated, Chandler, AZ (US)

(21) Appl. No.: 18/952,049

(22) Filed: Nov. 19, 2024

Related U.S. Application Data
(60) Provisional application No. 63/703,150, filed on Oct. 3, 2024.

(51) Int. Cl. H01L 25/065; H01L 21/02; H01L 21/311; H01L 23/00; H01L 29/04

(52) U.S. Cl. CPC H10W 90/00; H10D 62/405; H10P 14/3411; H10P 14/3416; H10P 14/3456; H10P 50/282; H10W 90/733

(57) ABSTRACT

There is a method for making a substrate by providing a Si top surface in a plane, and providing a GaN top surface in the plane adjacent the Si top surface, wherein a substrate is formed having a top surface comprising the Si top surface and the GaN top surface. There is a substrate having a Si top surface in a plane, and a GaN top surface in the plane adjacent the Si top surface. There is a package having a substrate with a Si top surface in a plane, and a GaN top surface in the plane adjacent the Si top surface, a CMOS chip attached to the Si top surface, a GaN transistor attached to the GaN top surface, and a metal layer connecting the CMOS chip and the GaN transistor.

### RELATED PATENT APPLICATION

This application claims priority to commonly owned U.S. Provisional Patent Application No. 63/703,150 filed Oct. 3, 2024, the entire contents of which are hereby incorporated by reference for all purposes.

### TECHNICAL FIELD

The present disclosure relates to GaN transistors and Si CMOS for applications such as GaN Power or RF devices with CMOS drivers, in particular, substrates for low impedance connections between GaN transistors and Si CMOS.

### BACKGROUND

Conventional GaN Power or RF devices are used with CMOS drivers by connecting separate dies via die-to-die wire bonding or other connections. For example, a multiple-stage amplifier may include a driver stage die and a final stage die. The driver stage die includes a first type of semiconductor substrate (e.g., a silicon substrate), a first transistor, and an integrated portion of an interstage impedance matching circuit. A control terminal of the first transistor is electrically coupled to an RF signal input terminal of the driver stage die, and the integrated portion of the interstage impedance matching circuit is electrically coupled between a current-carrying terminal of the first transistor and an RF signal output terminal of the driver stage die. The second die includes a III-V semiconductor substrate (e.g., a GaN substrate) and a second transistor. A connection, which is a non-integrated portion of the interstage impedance matching circuit, is electrically coupled between the RF signal output terminal of the driver stage die and an RF signal input terminal of the final stage die.

Devices have also been packaged together either in a single package or they have been connected on a board, but these implementations may produce higher impedance. Implementations have also bonded a thin layer of silicon onto an oxide above a plane of the GaN devices, which is a complicated process and the GaN devices end up on a different plane than the Si, making lithography and etching more challenging.

GaN fundamentally has poor intrinsic hole mobility, which may make integrating a driver difficult. Although GaN has high electron mobility, intrinsic hole mobility exhibits a very low value, which is a major limitation for use in power electronics and driver integration.

A difference between Silicon (1,0,0) and Silicon (1,1,1) is that Silicon (1,1,1) is typically preferred for high quality epitaxial growth normally associated with GaN devices and Silicon (1,0,0) is typically preferred for photolithography and device processing normally associated with typical CMOS drivers and integrated electronics.

There is a need to connect with low impedance GaN transistors and Si CMOS for applications such as GaN Power or RF devices with CMOS drivers.

### SUMMARY OF THE INVENTION

According to an aspect, there is provided a method comprising: providing a Si top surface in a plane; and providing a GaN top surface in the plane adjacent the Si top surface, wherein a substrate is formed having a top surface comprising the Si top surface and the GaN top surface.

An aspect provides a method as in the preceding paragraph, comprising: bonding a Si (1,0,0) layer and a Si (1,1,1) layer, wherein the Si top surface comprises Si (1,0,0) material or Si (1,1,1) material.

An aspect provides a method as in one of the preceding two paragraphs, comprising: depositing a mask; etching the mask to form an opening in the mask; and depositing a material in the opening in the mask.

An aspect provides a method as in one of the preceding three paragraphs, wherein the material comprises Si (1,0,0) material, Si (1,1,1) material, or GaN material.

An aspect provides a method as in one of the preceding four paragraphs, comprising: depositing poly silicon on the side walls of the opening to form a spacer between the Si top surface and the GaN top surface.

An aspect provides a method as in one of the preceding five paragraphs, comprising: depositing a buffer layer on the Si (1,1,1) layer; wherein providing a GaN top surface comprises depositing a GaN layer on the buffer layer; depositing a mask over the GaN layer; and etching the mask to form an opening in the mask, the GaN layer, and the buffer layer, wherein providing a Si top surface comprises depositing Si (1,0,0) material in the opening in the mask.

An aspect provides a method as in one of the preceding six paragraphs, comprising: depositing a mask over the Si (1,0,0) layer; and etching the mask to form an opening in the mask and Si (1,0,0) layer; wherein providing a GaN top surface comprises depositing a GaN layer in the opening in the mask.

An aspect provides a method as in one of the preceding seven paragraphs, comprising: providing a Si (1,1,1) layer; wherein providing a GaN top surface comprises depositing a GaN layer over the Si (1,1,1) layer; depositing a mask over the GaN layer; etching the mask to form an opening in the mask and the GaN layer; and wherein providing a Si top surface comprises depositing Si (1,1,1) material in the opening in the mask adjacent the GaN layer.

According to an aspect, there is provided a substrate comprising: a Si top surface in a plane; and a GaN top surface in the plane adjacent the Si top surface.

An aspect provides a substrate as in the preceding paragraph, wherein the Si top surface comprises Si (1,0,0) material or Si (1,1,1) material.

An aspect provides a substrate as in one of the preceding two paragraphs, comprising: a Si (1,0,0) layer bonded to a Si (1,1,1) layer.

An aspect provides a substrate as in one of the preceding three paragraphs, comprising: a GaN layer over the Si (1,1,1) layer and comprising the GaN top surface; and a Si (1,0,0) growth connected to the Si (1,0,0) layer and comprising the Si top surface.

An aspect provides a substrate as in one of the preceding four paragraphs, comprising: a buffer layer between the GaN layer and the Si (1,1,1) layer.

An aspect provides a substrate as in one of the preceding five paragraphs, comprising: a spacer between the GaN layer and the Si (1,0,0) growth, wherein the spacer comprises poly silicon.

An aspect provides a substrate as in one of the preceding six paragraphs, comprising: a GaN growth over the Si (1,1,1) layer and comprising the GaN top surface.

An aspect provides a substrate as in one of the preceding seven paragraphs, comprising: a Si (1,1,1) layer; a GaN layer over the Si (1,1,1) layer and comprising the GaN top surface; and a Si (1,1,1) growth connected to the Si (1,1,1) layer and comprising the Si top surface.

According to an aspect, there is provided a package comprising: a substrate comprising: a Si top surface in a plane; and a GaN top surface in the plane adjacent the Si top surface; a CMOS chip attached to the Si top surface; a GaN transistor attached to the GaN top surface; and a metal layer connecting the CMOS chip and the GaN transistor.

An aspect provides a package as in the preceding paragraph, wherein the substrate comprises: a Si (1,0,0) layer bonded to a Si (1,1,1) layer; a GaN layer over the Si (1,1,1) layer and comprising the GaN top surface; and a Si (1,0,0) growth connected to the Si (1,0,0) layer and comprising the Si top surface.

An aspect provides a package as in one of the preceding two paragraphs, wherein the substrate comprises: a Si (1,0,0) layer comprising the Si top surface and bonded to a Si (1,1,1) layer; and a GaN growth over the Si (1,1,1) layer and comprising the GaN top surface.

An aspect provides a package as in one of the preceding three paragraphs, wherein the substrate comprises: a Si (1,1,1) layer; a GaN layer over the Si (1,1,1) layer and comprising the GaN top surface; and a Si (1,1,1) growth connected to the Si (1,1,1) layer and comprising the Si top surface.

### BRIEF DESCRIPTION OF THE DRAWINGS

The figures illustrate examples of substrates for low impedance GaN transistors and Si CMOS for applications such as GaN Power or RF devices with CMOS drivers.

FIG. 1A shows a cross-sectional, side view of a semiconductor substrate.

FIG. 1B shows a cross-sectional, side view of the semiconductor substrate of FIG. 1A with a Si (1,0,0) added.

FIG. 1C shows a cross-sectional, side view of the semiconductor substrate of FIG. 1B with a mask added.

FIG. 1D shows a cross-sectional, side view of the semiconductor substrate of FIG. 1C with an etch through the mask.

FIG. 1E shows a cross-sectional, side view of the semiconductor substrate of FIG. 1D with spacers added.

FIG. 1F shows a cross-sectional, side view of the semiconductor substrate of FIG. 1E with a Si (1,0,0) growth added.

FIG. 2 shows a cross-sectional, side view of an integrated semiconductor substrate with a GaN die and a CMOS driver die connected via a redistribution layer or other substrate connection to provide a low impedance connection.

FIG. 3A shows a cross-sectional, side view of a semiconductor substrate.

FIG. 3B shows a cross-sectional, side view of the semiconductor substrate of FIG. 3A with a mask.

FIG. 3C shows a cross-sectional, side view of the semiconductor substrate of FIG. 3B with an etch through the mask.

FIG. 3D shows a cross-sectional, side view of the semiconductor substrate of FIG. 3C with a GaN die and a CMOS driver die connected via a redistribution layer or other substrate connection to provide a low impedance connection.

FIG. 4A shows a cross-sectional, side view of a semiconductor substrate.

FIG. 4B shows a cross-sectional, side view of the semiconductor substrate of FIG. 4A with a mask.

FIG. 4C shows a cross-sectional, side view of the semiconductor substrate of FIG. 4B with an etch through the mask.

FIG. 4D shows a cross-sectional, side view of the semiconductor substrate of FIG. 4C with a growth in the etch.

FIG. 4E shows a cross-sectional, side view of the semiconductor substrate of FIG. 4D with a GaN die and a CMOS driver die connected via a redistribution layer or other substrate connection to provide a low impedance connection.

FIG. 5 shows a flow chart of a method for making a substrate to integrate GaN transistors and Si CMOS monolithically for applications such as integrating GaN Power or RF devices with CMOS drivers, with low impedance.

FIG. 6 shows a cross-sectional side view of a substrate having a Si top surface in a plane and a GaN top surface in the plane adjacent the Si top surface.

FIG. 7 shows a cross-sectional side view of a package.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

Aspects integrate GaN transistors and Si CMOS monolithically for applications such as integrating GaN Power or RF devices with CMOS drivers, with low impedance. A monolithic integration with silicon may overcome GaN fundamental poor intrinsic hole mobility. A monolithic integration with silicon (1,0,0) and GaN may enable reuse of available MCUs, MPUs, Analog, FPGAs, without limitation for direct integration with a GaN switch.

According to an aspect, there is provided a method to place all devices in the same plane so they can be wired together directly through metal lines. Silicon devices and GaN devices may be built on the same wafer, in the same plane, and wired directly together through metal layers, without connections through RDL layers or wirebonds. A direct wire connection through metal layers may provide a low impedance connection between Si and GaN devices. A direct wire connection through metal layers may provide less parasitic inductance (and therefore energy loss) than either a wire bond or a fan out re-distribution layer.

The process of building a substrate for Si and GaN devices to be mounted on the same plane may simplify photolithography and allow for existing design MCUs, MPUs, Analog, FPGAs, without limitation to be reused in the CMOS areas of the substrate. The process applies to all monolithic Si and GaN integrations where there is growth or re-growth of an epitaxy (EPI) layer regardless of how the transition layers are grown.

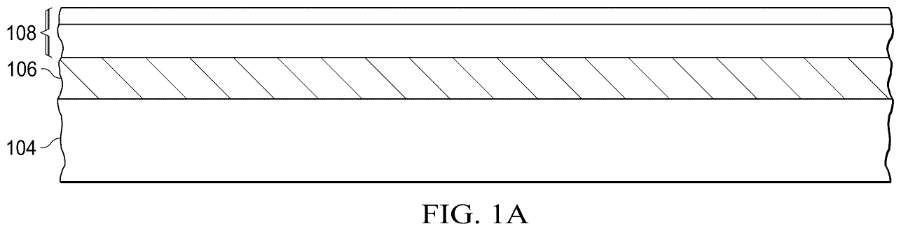

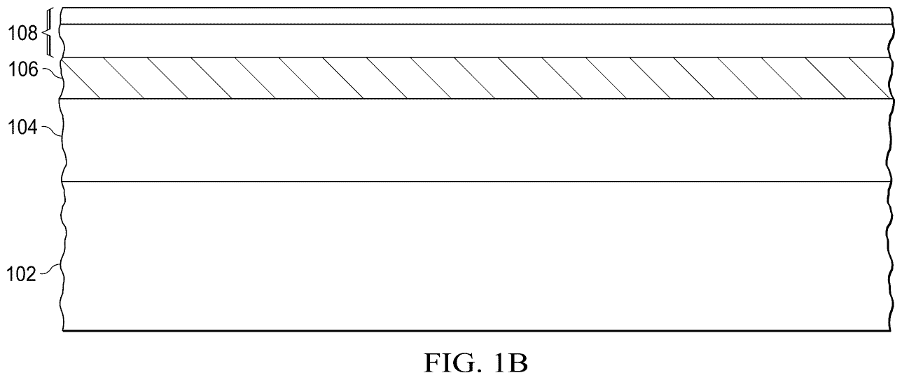

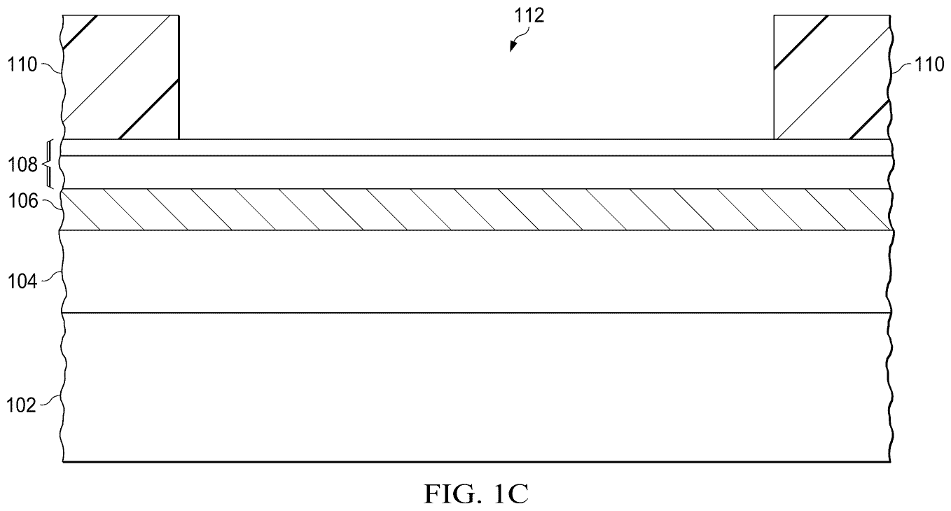

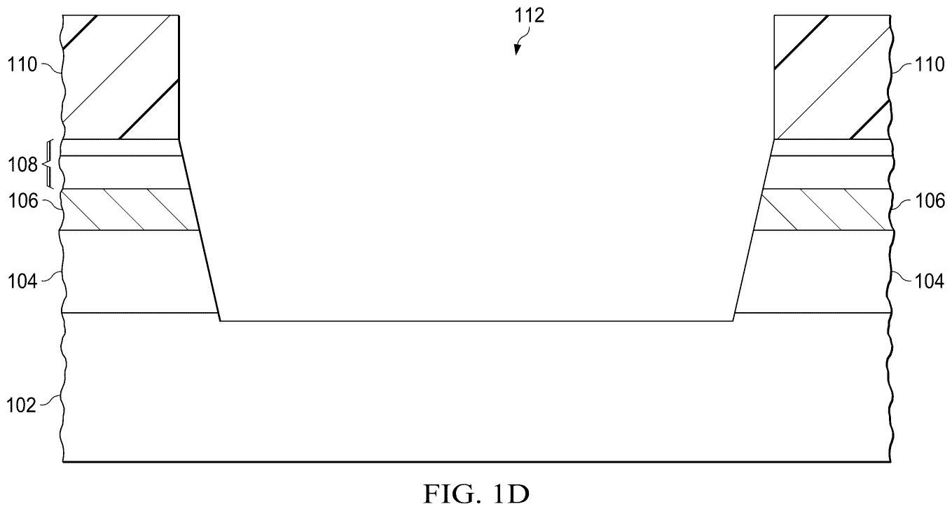

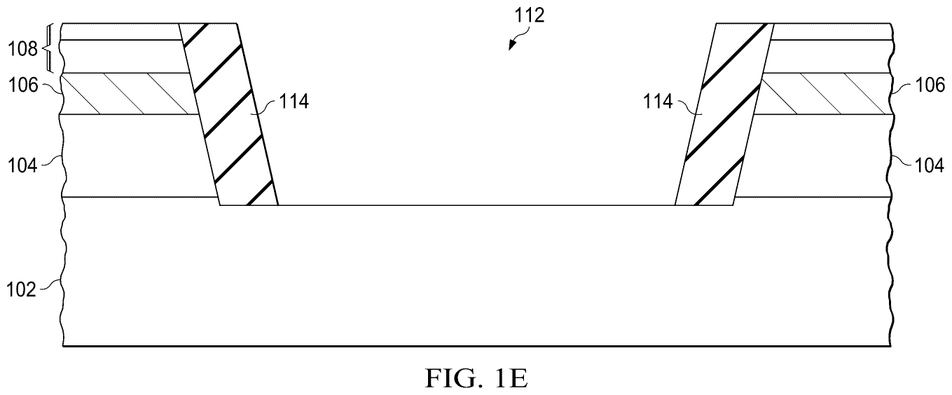

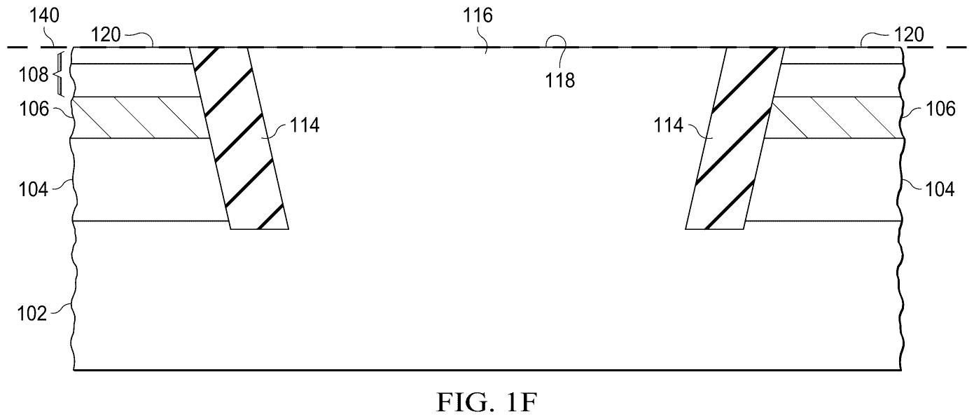

FIG. 1A shows a cross-sectional, side view of a semiconductor substrate. A Si (1,1,1) layer 104 has a buffer layer 106 bonded on the Si (1,1,1) layer 104. The buffer layer 106 may be like aluminum nitride (AlN) and may be grown by metalorganic chemical vapor deposition (MOCVD). A GaN layer 108 may be an epitaxy (EPI) layer grown by metalorganic chemical vapor deposition (MOCVD) on the buffer layer 106. The GaN layer 108 may be a GaN stack that may include any layer on the GaN, such as a GaN cap layer, an AlGaN barrier layer, or a silicon nitride cap layer, without limitation. The Si (1,1,1) layer 104 could be replaced by SiC or p-SiC. The substrate shown in FIG. 1A may be supplied by a vendor, foundry, or integrated device manufacturer.

FIG. 1B shows a cross-sectional, side view of the semiconductor substrate of FIG. 1A. A Si (1,0,0) layer 102 is bonded on the Si (1,1,1) layer 104. The Si (1,0,0) layer 102 may be 300-800μm.

FIG. 1C shows a cross-sectional, side view of the semiconductor substrate of FIG. 1B. A noncritical mask 110 is deposited on the GaN layer 108 and an opening 112 is etched in the mask 110 where Si CMOS is to be positioned.

FIG. 1D shows a cross-sectional, side view of the semiconductor substrate of FIG. 1C. The substrate is etched through the GaN layer 108, the buffer layer 106, and the Si (1,1,1) layer 104, and is further etched into a portion of the Si (1,0,0) layer 102.

FIG. 1E shows a cross-sectional, side view of the semiconductor substrate of FIG. 1D. A spacer 114 is built in the etched opening 112 by deposit and etch. The spacer 114 may be applied to the side walls of the opening 112 and may be poly silicon. The spacer 114 is optional, so that embodiments may not have a spacer 114.

FIG. 1F shows a cross-sectional, side view of the semiconductor substrate of FIG. 1E. A Si (1,0,0) growth 116 is deposited or grown on the Si (1,0,0) layer 102 to fill the opening 112 (see FIG. 1E) to the level of the GaN layer 108. A top surface 118 of the Si (1,0,0) growth 116 is in the same plane 140 (shown as a dotted line in the side view of FIG. 1F) as a top surface 120 of the GaN layer 108. The Si(1,0,0) top surface 118 and the GaN top surface 120 are described and illustrated as being in the same plane 140, wherein “being in the same plane” is defined as being close enough to being in the same plane to allow devices mounted on the top surfaces to be connected by a redistribution layer or other low impedance connection.

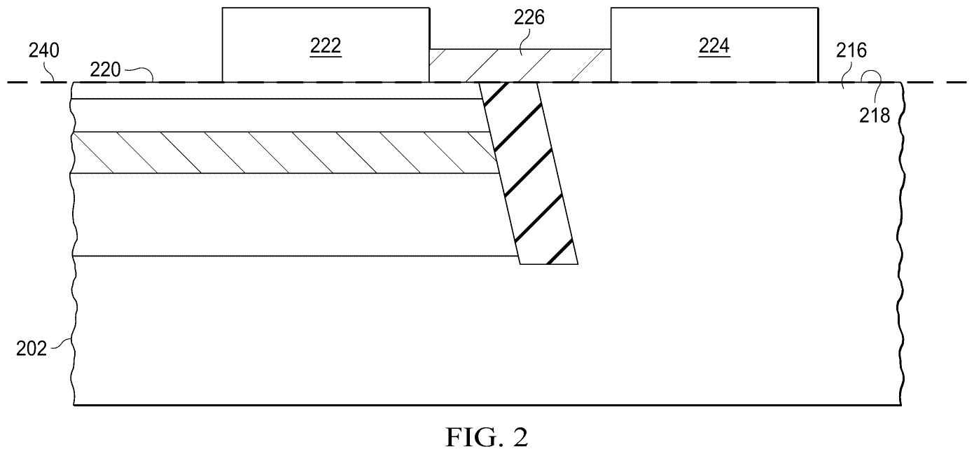

FIG. 2 shows a cross-sectional, side view of dies mounted on a GaN/Si integrated semiconductor substrate. The substrate has a Si (1,0,0) top surface 218 in the same plane 240 as a GaN top surface 220. A GaN die 222, which may be a GaN power die or a RF device, is mounted on the GaN top surface 220. A CMOS driver die 224 may be mounted on the Si (1,0,0) top surface 218. Thus, the GaN die 222 and the CMOS driver die 224 may be connected via a redistribution layer 226 or other substrate connection to provide a low impedance connection. For example, a 100V˜1200V HEMT-WBG switch may be mounted on the GaN top surface 220 and low Vdd 1V˜5V (MPU, Analog, MCU, FFGA, without limitation) mid Vdd 9V˜48V CMOS circuit may be mounted on the Si (1,0,0) top surface 218.

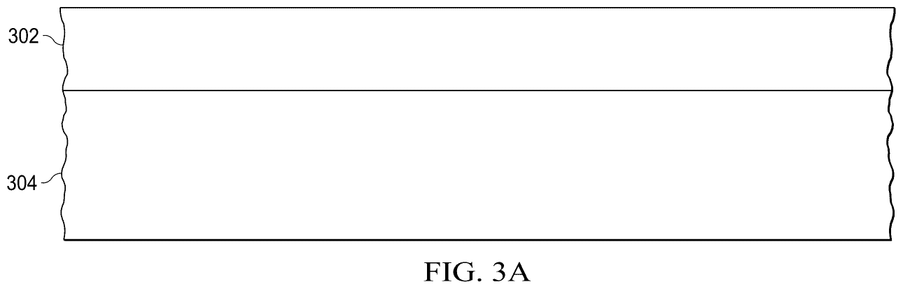

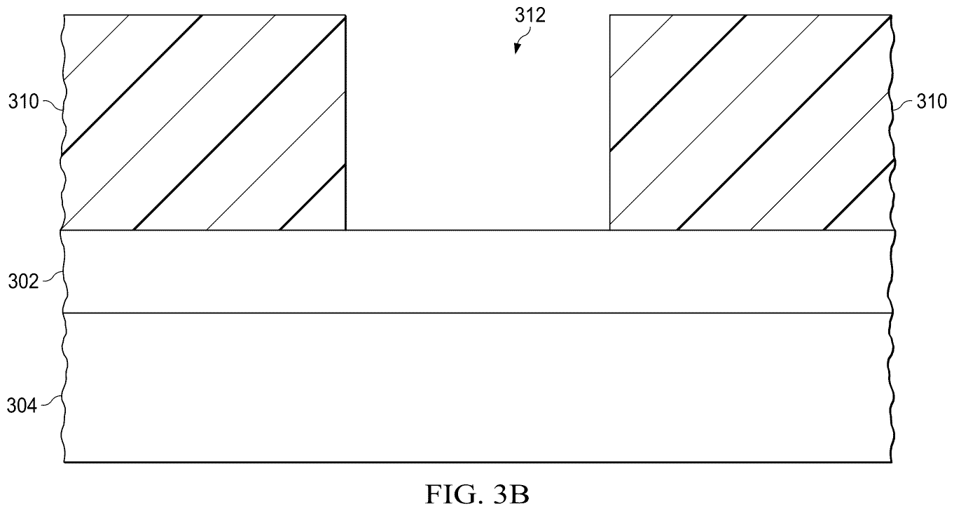

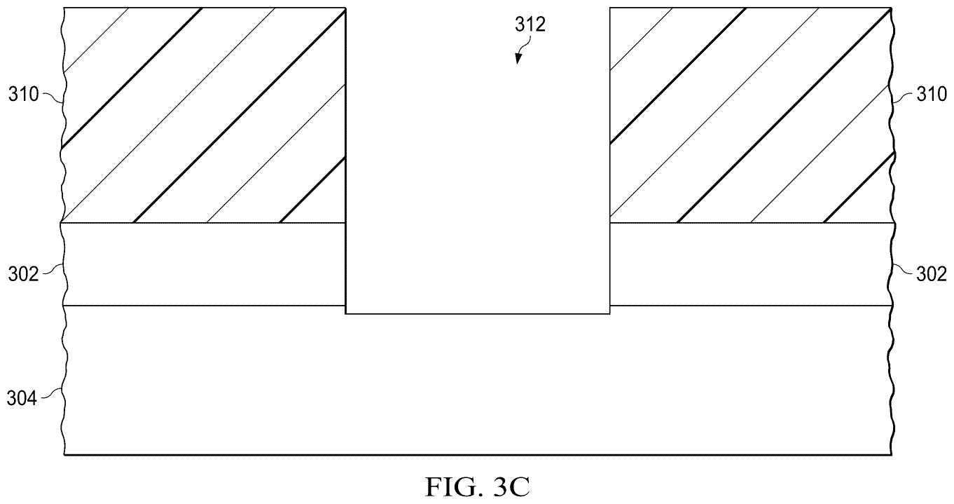

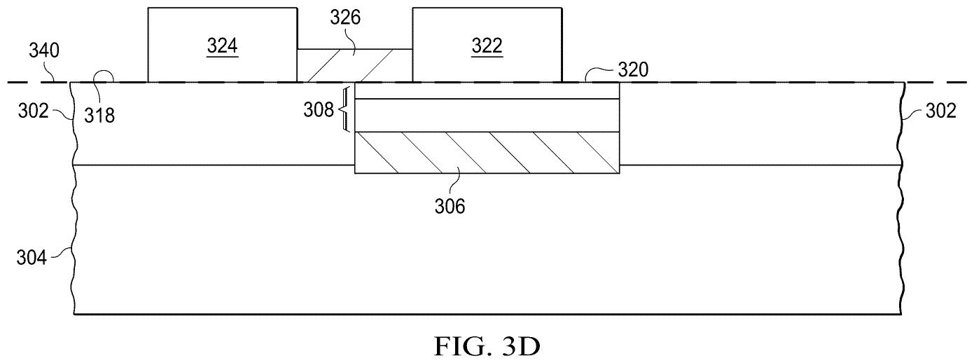

FIG. 3A shows a cross-sectional, side view of a semiconductor substrate. A Si (1,0,0) layer 302 is bonded on a Si (1,1,1) layer 304. Alternatively, the Si (1,1,1) layer 304 may be SiC. The Si (1,0,0) layer 302 may be 300-800μm.

FIG. 3B shows a cross-sectional, side view of the semiconductor substrate of FIG. 3A. A noncritical mask 310 is deposited on the Si (1,0,0) layer 302 and an opening 312 is etched in the mask 310 where Si CMOS is to be positioned.

FIG. 3C shows a cross-sectional, side view of the semiconductor substrate of FIG. 3B. The substrate is etched through Si (1,0,0) layer 302 to the Si (1,1,1) layer 304 at opening 312. A spacer (not shown) could optionally be added in the opening 312.

FIG. 3D shows a cross-sectional, side view of the semiconductor substrate of FIG. 3C. A buffer layer 306 may be bonded on the Si (1,1,1) layer 304. The buffer layer 306 may be aluminum nitride (AlN) and may be grown by metalorganic chemical vapor deposition (MOCVD). A GaN layer 308 may be grown by epitaxy (EPI) on the buffer layer 306. The Si (1,1,1) layer 304 could be replaced by SiC or p-SiC. The substrate has a Si (1,0,0) top surface 318 in the same plane 340 (shown as a dotted line in the side view of FIG. 3D) as a GaN top surface 320. A GaN die 322, which may be a GaN power die or a RF device, is mounted on the GaN top surface 220. A CMOS driver die 324 may be mounted on the Si (1,0,0) top surface 318. Thus, the GaN die 322 and the CMOS driver die 324 may be connected via a redistribution layer 326 or other substrate connection to provide a low impedance connection.

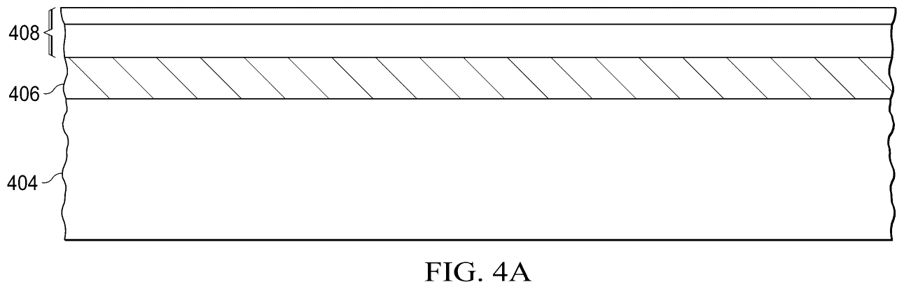

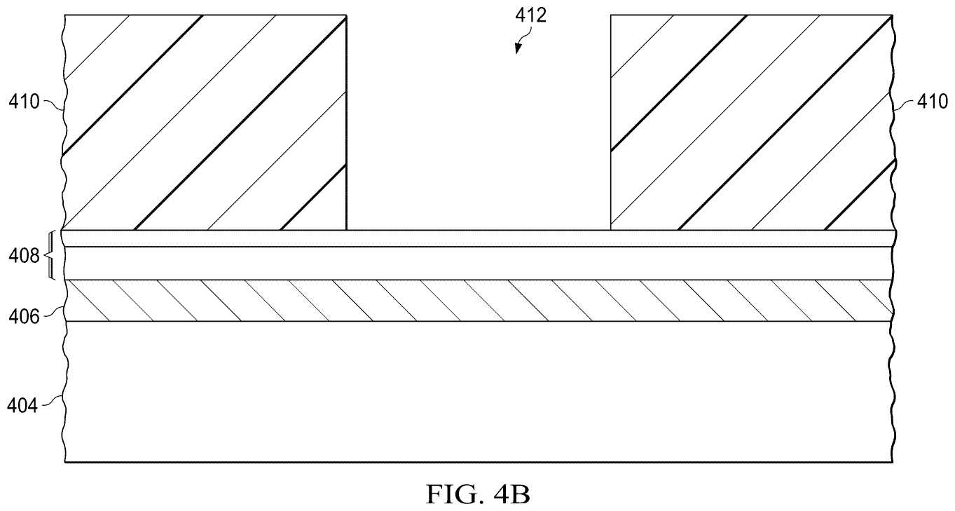

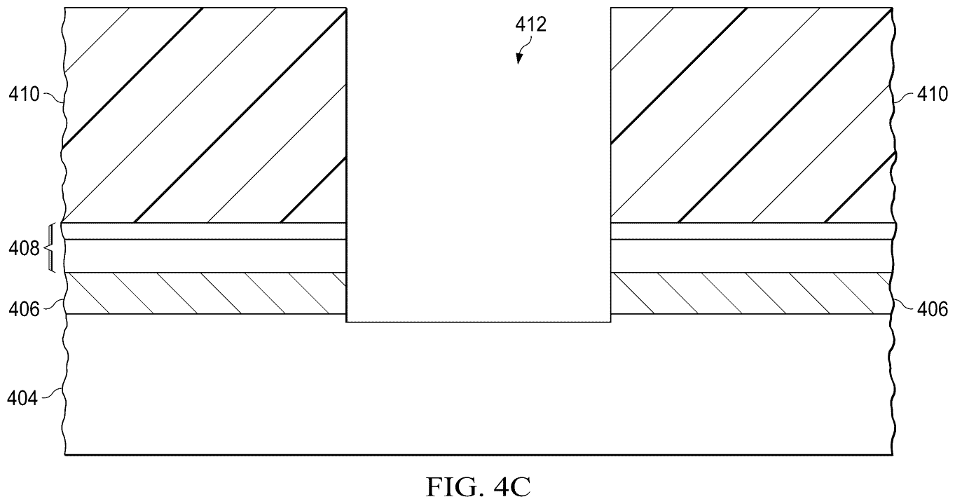

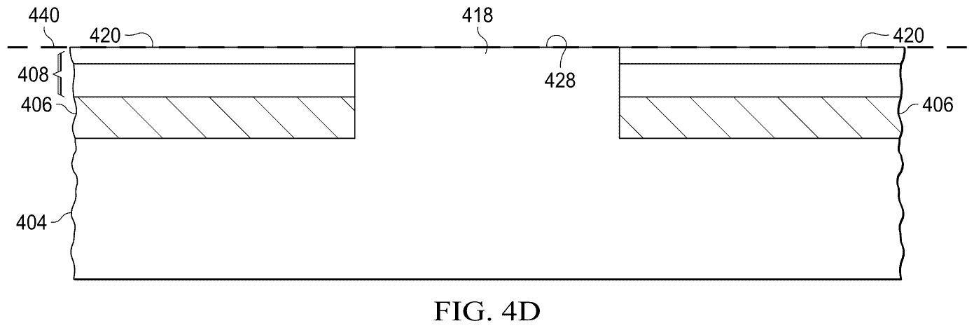

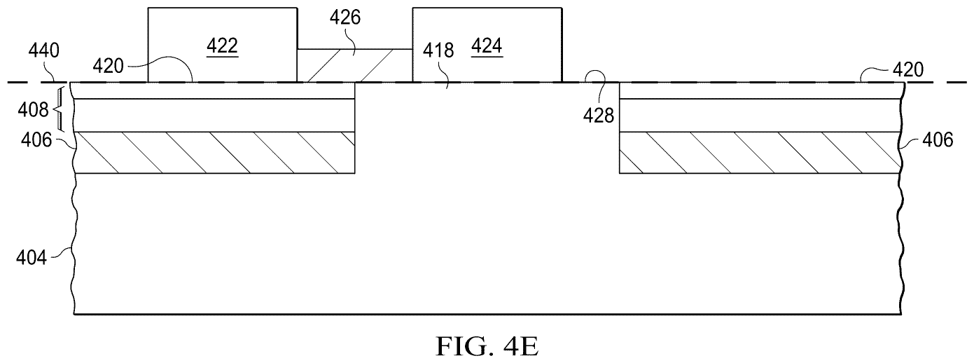

FIG. 4A shows a cross-sectional, side view of a semiconductor substrate. A Si (1,1,1) layer 404 or SiC is provided. A buffer layer 406 may be bonded on the Si (1,1,1) layer 404. The buffer layer 406 may be aluminum nitride (AlN) and may be grown by metalorganic chemical vapor deposition (MOCVD). A GaN layer 408 may be grown by epitaxy (EPI) on the buffer layer 406. The Si (1,1,1) layer 404 could be replaced by SiC or p-SiC.

FIG. 4B shows a cross-sectional, side view of the semiconductor substrate of FIG. 4A. A noncritical mask 410 is deposited on the GaN layer 408 and an opening 412 is etched in the mask 410 where Si CMOS is to be positioned.

FIG. 4C shows a cross-sectional, side view of the semiconductor substrate of FIG. 4B. The substrate is etched through the GaN layer 408 and the buffer layer 406 down to the Si (1,1,1) layer 404. A spacer could optionally be added.

FIG. 4D shows a cross-sectional, side view of the semiconductor substrate of FIG. 4C. A Si (1,1,1) growth 418 is deposited or grown on the Si (1,1,1) layer 404 to fill the opening 412 to the level of the GaN layer 408. The substrate has a Si (1,1,1) top surface 428 in the same plane 440 (shown as a dotted line in the side view of FIG. 4D) as a GaN top surface 420.

FIG. 4E shows a cross-sectional, side view of the semiconductor substrate of FIG. 4D. The substrate has a Si (1,1,1) top surface 428 in the same plane 440 as a GaN top surface 420. A GaN die 422, which may be a GaN power die or a RF device, is mounted on the GaN top surface 420. A CMOS driver die 424 may be mounted on the Si (1,1,1) top surface 428. Thus, the GaN die 422 and the CMOS driver die 424 may be connected via a redistribution layer 426 or other substrate connection to provide a low impedance connection.

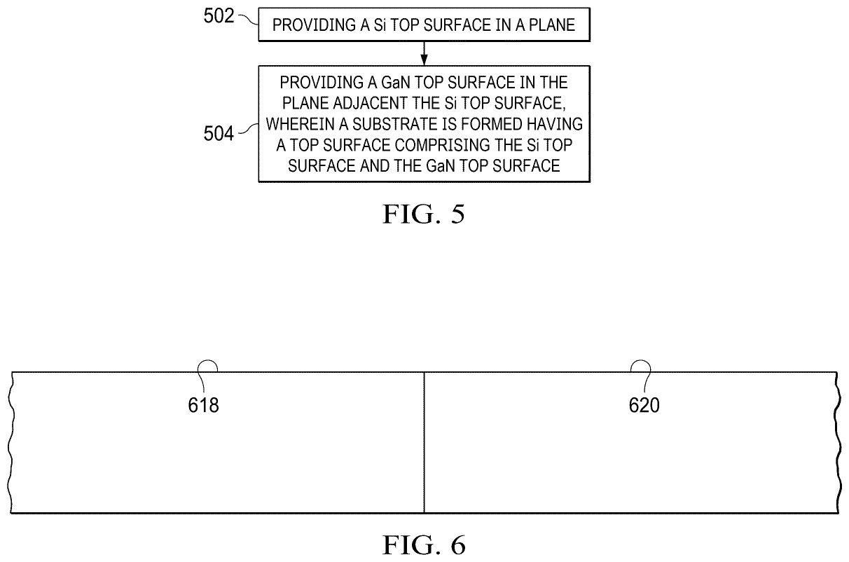

FIG. 5 shows a flow chart of a method for making a substrate to integrate GaN transistors and Si CMOS monolithically for applications such as integrating GaN Power or RF devices with CMOS drivers, with low impedance. A Si top surface is provided 502 in a plane. A GaN top surface is provided 504 in the plane adjacent the Si top surface. A substrate is formed having a top surface comprising the Si top surface and the GaN top surface.

FIG. 6 shows a cross-sectional side view of a substrate. The substrate has a Si top surface 618 in a plane. The substrate also has a GaN top surface 620 in the plane adjacent the Si top surface 618.

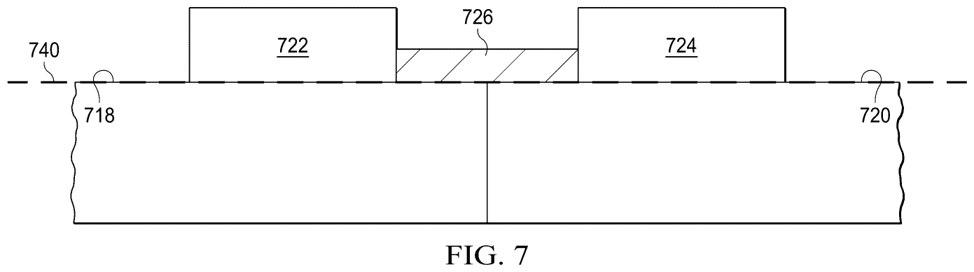

FIG. 7 shows a cross-sectional side view of a package. The package has a substrate comprising: a Si top surface 718 in a plane 740, and a GaN top surface 720 in the plane 740 adjacent the Si top surface 718. A CMOS chip 722 is attached to the Si top surface 718. A GaN transistor 724 is attached to the GaN top surface 720. A metal layer 726 connects the CMOS chip 722 and the GaN transistor 724.

Although examples have been described above, other variations and examples may be made from this disclosure without departing from the spirit and scope of these disclosed examples.

1. A method comprising:
providing a Si top surface in a plane; and
providing a GaN top surface in the plane adjacent the Si top surface,
wherein a substrate is formed having a top surface comprising the Si top surface and the GaN top surface.

2. The method of claim 1, comprising:
bonding a Si (1,0,0) layer and a Si (1,1,1) layer,
wherein the Si top surface comprises Si (1,0,0) material or Si (1,1,1) material.

3. The method of claim 1, comprising:
depositing a mask;
etching the mask to form an opening in the mask; and
depositing a material in the opening in the mask.

4. The method of claim 3, wherein the material comprises Si (1,0,0) material, Si (1,1,1) material, or GaN material.

5. The method of claim 3, comprising:
depositing poly silicon on the side walls of the opening to form a spacer between the Si top surface and the GaN top surface.

6. The method of claim 2, comprising:
depositing a buffer layer on the Si (1,1,1) layer;
wherein providing a GaN top surface comprises depositing a GaN layer on the buffer layer;
depositing a mask over the GaN layer; and
etching the mask to form an opening in the mask, the GaN layer, and the buffer layer,
wherein providing a Si top surface comprises depositing Si (1,0,0) material in the opening in the mask.

7. The method of claim 2, comprising:
depositing a mask over the Si (1,0,0) layer; and
etching the mask to form an opening in the mask and Si (1,0,0) layer;
wherein providing a GaN top surface comprises depositing a GaN layer in the opening in the mask.

8. The method of claim 1, comprising:
providing a Si (1,1,1) layer, wherein providing a GaN top surface comprises depositing a GaN layer over the Si (1,1,1) layer;
depositing a mask over the GaN layer; and
etching the mask to form an opening in the mask and the GaN layer, wherein providing a Si top surface comprises depositing Si (1,1,1) material in the opening in the mask adjacent the GaN layer.

9. A substrate comprising:
a Si top surface in a plane; and
a GaN top surface in the plane adjacent the Si top surface.

10. The substrate of claim 9, wherein the Si top surface comprises Si (1,0,0) material or Si (1,1,1) material.

11. The substrate of claim 9, comprising:
a Si (1,0,0) layer bonded to a Si (1,1,1) layer.

12. The substrate of claim 11, comprising:
a GaN layer over the Si (1,1,1) layer and comprising the GaN top surface; and
a Si (1,0,0) growth connected to the Si (1,0,0) layer and comprising the Si top surface.

13. The substrate of claim 12, comprising:
a buffer layer between the GaN layer and the Si (1,1,1) layer.

14. The substrate of claim 12, comprising:
a spacer between the GaN layer and the Si (1,0,0) growth, wherein the spacer comprises poly silicon.

15. The substrate of claim 11, comprising:
a GaN growth over the Si (1,1,1) layer and comprising the GaN top surface.

16. The substrate of claim 9, comprising:
a Si (1,1,1) layer;
a GaN layer over the Si (1,1,1) layer and comprising the GaN top surface; and
a Si (1,1,1) growth connected to the Si (1,1,1) layer and comprising the Si top surface.

17. A package comprising:
a substrate comprising:
a Si top surface in a plane; and
a GaN top surface in the plane adjacent the Si top surface;
a CMOS chip attached to the Si top surface;
a GaN transistor attached to the GaN top surface; and
a metal layer connecting the CMOS chip and the GaN transistor.

18. The package of claim 17, wherein the substrate comprises:
a Si (1,0,0) layer bonded to a Si (1,1,1) layer;
a GaN layer over the Si (1,1,1) layer and comprising the GaN top surface; and
a Si (1,0,0) growth connected to the Si (1,0,0) layer and comprising the Si top surface.

19. The package of claim 17, wherein the substrate comprises:
a Si (1,0,0) layer comprising the Si top surface and bonded to a Si (1,1,1) layer; and
a GaN growth over the Si (1,1,1) layer and comprising the GaN top surface.

20. The package of claim 17, wherein the substrate comprises:
a Si (1,1,1) layer;
a GaN layer over the Si (1,1,1) layer and comprising the GaN top surface; and
a Si (1,1,1) growth connected to the Si (1,1,1) layer and comprising the Si top surface.
